(19) United States
(12) Patent Application Publication
(10) Pub. No.: US 2012/0308733 A1
(43) Pub. Date: Dec. 6, 2012

(54) METHOD OF MANUFACTURING A THERMAL BARRIER COATING STRUCTURE

(76) Inventors: Konstantin von Niessen, Buttwil (CH); Malko Gindrat, Wohlen (CH); Richard K. Schmid, Gerlikon (CH)

(21) Appl. No.: 13/268,045

(22) Filed: Oct. 7, 2011

(30) Foreign Application Priority Data
Oct. 11, 2010 (EP) 10187182.0

(51) Int. Cl. C23C 4/12; C23C 14/24; C23C 16/513

(52) U.S. Cl. 427/454; 427/446; 118/620; 427/453; 427/569; 118/723 R; 204/192.38

(57) ABSTRACT

To manufacture a thermal barrier coating structure on a substrate surface, a working chamber having a plasma torch is provided, a plasma jet is generated in that a plasma gas is conducted through the plasma torch and is heated therein by means of electric gas discharge, electromagnetic induction or microwaves, and the plasma jet is directed to the surface of a substrate introduced into the working chamber. To manufacture the thermal barrier coating, a voltage is additionally applied between the plasma torch and the substrate to generate an arc between the plasma torch and the substrate and the substrate surface is cleaned by means of the light arc, wherein the substrate remains in the working chamber after the arc cleaning and an oxide layer is generated on the cleaned substrate surface and a thermal barrier coating is applied by means of a plasma spray process.

The invention relates to a method of manufacturing a thermal barrier coating structure on a substrate surface in accordance with the preamble of claim 1 and to a substrate manufactured using such a method.

Thermal barrier coatings are used in machines and processes to protect parts subject to high thermal strain from the effect of heat, hot gas corrosion and erosion. An increase in the efficiency of machines and processes is frequently only possible with an increase of the process temperature so that exposed parts have to be protected accordingly. The turbine blades in aircraft engines and stationary gas turbines are thus, for example, normally provided with a single-layer or multilayer thermal barrier coating system to protect the turbine blades from the effect of the high process temperatures and to extend the servicing intervals and the service life.

A thermal barrier coating system can contain one or more layers in dependence on the application, for example a barrier layer, in particular a diffusion barrier layer, an adhesion promoting layer, a hot gas corrosion protective layer, a protective layer, a thermal barrier coating and/or a cover layer. In the example of the above-mentioned turbine blades, the substrate is usually manufactured from an Ni alloy or a Co alloy. The thermal barrier coating system applied to the turbine blade can, for example, contain the following layers in rising order:
a metallic barrier layer, for example from NiAl phases or NiCr phases or alloys;
a metallic adhesion promoting layer which also serves as a hot gas corrosion protective layer and which can be manufactured, for example, at least partly from a metal aluminide or from an MCrAlY alloy, where M stands for one of the metals Fe, Ni or Co or a combination of Ni and Co;
an oxide ceramic protective layer, for example predominantly of Al₂O₃ or of other oxides;
an oxide ceramic thermal barrier coating, for example of stabilized zirconium oxide; and
an oxide ceramic smoothing layer or cover layer, for example of stabilized zirconium oxide or SiO₂.

The thermal barrier coating structure, whose manufacture will be described in the following, contains at least one oxide ceramic protective layer and at least one oxide ceramic thermal barrier coating. This thermal barrier coating structure is applied to a metallic substrate surface which, as in the example of the above-mentioned turbine blade, can be provided by a metallic adhesion promoting layer and/or a hot gas corrosion protective layer.

In document U.S. Pat. No. 5,238,752, the manufacture of a thermal barrier coating structure is described which is applied to a metallic substrate surface. The substrate itself is composed of an Ni alloy or Co alloy, whereas the metallic substrate surface is formed by a 25 μm thick to 125 μm thick adhesion promoting layer of Ni aluminide or Pt aluminide. An oxide ceramic protective layer, 0.03 μm to 3 μm thick and of Al₂O₃, is generated on this substrate surface and an oxide ceramic thermal barrier coating, 125 μm to 725 μm thick and of ZrO₂ and 6%-20% Y₂O₃ is subsequently deposited by means of electron beam physical vapor deposition (EB-PVD). In the EB-PVD process, the substance to be deposited for the thermal barrier coating, e.g. Zr₂ with 8% Y₂O₃, is brought into the vapor phase by an electron beam in a high vacuum and is condensed from said vapor phase on the component to be coated. If the process parameters are selected in a suitable manner, a columnar microstructure results.

The manufacture of a thermal barrier coating structure described in U.S. Pat. No. 5,238,752 has the disadvantage that the plant costs for the deposition of the thermal barrier coating by means of EB-PVD are comparatively high and that EB-PVD does not allow any non line-of-sight (NLOS) application of the thermal barrier coating, whereas it is, for example, possible with low pressure plasma spraying (LPPS) also to coat parts of the substrate which are disposed behind an edge and are not visible from the plasma torch.

It is known from WO 03/087422 A1 that thermal barrier coatings can also be manufactured with a columnar structure by means of an LPPS thin-film process. In the plasma spray process described in WO 03/087422 A1, a material to be coated is sprayed onto a surface of a metallic substrate by means of a plasma jet. In this respect, the coating material is injected into a plasma defocusing the powder jet and is partly or completely melted there at a low process pressure, which is smaller than 10 mbar. For this purpose, a plasma with a sufficiently high specific enthalpy is generated, so that a substantial portion, amounting to at least 5% by weight of the coating material, changes into the vapor phase. An anisotropic structured layer is applied to the substrate with the coating material. In this layer, elongate corpuscles which form an anisotropic microstructure are aligned standing largely perpendicular to the substrate surface, wherein the corpuscles are delineated from one another by low-material transition regions and consequently form a columnar structure.

The plasma spray process described in WO 03/087422 A1 for manufacturing thermal barrier coatings having a columnar structure is mentioned in connection with LPPS thin-film processes since, like these, it uses a wide plasma jet which arises by the pressure difference between the pressure in the interior of the plasma torch of typically 100 kPa and the pressure in the working chamber of less than 10 kPa. Since, however, the thermal barrier coatings generated using the described process can be up to 1 mm thick or thicker and are thus practically not covered by the term “thin film”, the described method will in the following be called a plasma spray physical vapor deposition process or in abbreviation PS-PVD.

The applicant has found that the temperature change resistance of thermal barrier coating systems which contain a thermal barrier coating manufactured in accordance with WO 03/087422 A1 can be improved if a thermal barrier coating structure manufactured in accordance with a modified process is used.

It is the object of the invention to provide a method of manufacturing a thermal barrier coating structure on a substrate surface with which the temperature change resistance of thermal barrier coating systems having thermal barrier coatings which are manufactured by means of a plasma spray process can be improved.

This object is satisfied in accordance with the invention by the method defined in claim 1.

In the method in accordance with the invention of manufacturing a thermal barrier coating structure on a substrate surface, a working chamber is provided having a plasma torch, a plasma jet is generated in that a plasma gas is conducted through the plasma torch and is heated therein by means of electric gas discharge and/or electromagnetic induction and/or microwaves and the plasma jet is directed to the surface of a substrate introduced into the working chamber. In the method of manufacturing a thermal barrier coating structure, a voltage is additionally applied between the plasma torch and the substrate to generate an arc between the plasma torch and the substrate and the substrate surface is cleaned by means of the arc, with the substrate remaining in the working chamber after the arc cleaning. An oxide layer having a thickness of 0.02 μm to 5 μm or 0.02 μm to 2 μm is generated on the substrate surface cleaned in this manner and in a further step at least one thermal barrier coating is applied by means of a plasma spray process. The substrate advantageously remains in the working chamber during the manufacture of the thermal barrier coating structure, typically during the duration of the whole process.

The substrate and/or the substrate surface is/are typically metallic, wherein the substrate surface can be formed, for example, by an adhesion promoting layer and/or a hot gas corrosion protective layer, for example a layer of a metal aluminide such as NiAl, NiPtAl or PtAl or an alloy of the type MCrAlY, where M=Fe, Co, Ni or NiCo. If required, the adhesion promoting layer and/or the hot gas corrosion protective layer can be applied to the substrate surface before the above-described thermal barrier coating structure by means of a plasma spray process or by means of another suitable process.

In an advantageous embodiment, the composition and/or the pressure of the atmosphere in the working chamber is/are monitored and/or controlled during the manufacture of the thermal barrier coating structure. In an advantageous embodiment variant, the pressure in the working chamber during the arc cleaning of the substrate surface amounts to less than 1 kPa.

In a further advantageous embodiment variant, the working chamber contains oxygen or a gas containing oxygen during the generation of the oxide layer. The oxide layer can, for example, be thermally generated in that the substrate surface is heated, for example, by the plasma jet.

The oxide layer can also be generated by means of PS-PVD or by means of a chemical plasma spray chemical vapor deposition (PS-CVD), wherein the pressure in the working chamber typically lies below 1 kPa and wherein, as required, at least one reactive component is injected into the plasma jet in solid and/or liquid and/or gaseous form.

The oxide layer generated advantageously has a porosity of less than 3% or less than 1% and/or more than 90% or more than 95% is formed from a thermally stable oxide, i.e. from an oxide such as α-Al₂O₃ which is thermally stable under the conditions of use of the substrate.

In a further advantageous embodiment, the at least one thermal barrier coating is manufactured from ceramic material, wherein the ceramic material can be composed, for example, of zirconium oxide, in particular zirconium oxide stabilized with yttrium, cerium, scandium, dysprosium or gadolinium and/or can contain zirconium oxide, in particular zirconium oxide stabilized with yttrium, cerium, scandium, dysprosium or gadolinium.

In an advantageous embodiment variant, the at least one thermal barrier coating is applied by means of thermal plasma spraying at a pressure in the working chamber of more than 50 kPa and/or by means of low pressure plasma spraying (LPPS) at a pressure in the working chamber of 5 kPa to 50 kPa.

In a further advantageous embodiment variant, the at least one thermal barrier coating is applied by means of plasma spray physical vapor deposition (PS-PVD) at a pressure in the working chamber of less than 5 kPa and typically less than 1 kPa, wherein the ceramic material can, for example, be injected into a plasma defocusing the powder jet. The ceramic material is advantageously at least partly vaporized in the plasma jet so that, for example, at least 15% by weight or at least 20% by weight changes into the vapor phase to generate a thermal barrier coating having a columnar structure.

In a further advantageous embodiment, the direction of the plasma jet and/or the spacing of the plasma torch from the substrate is/are controlled. In this manner, the plasma jet can be conducted over the substrate surface, for example on the cleaning of the substrate surface and/or on the heating of the substrate surface and/or on application of the at least one thermal barrier coating.

The invention further includes a substrate manufactured using the above-described method or using one of the above-described embodiments and variants.

The method of manufacturing a thermal barrier coating structure in accordance with the present invention has the advantage that, thanks to the cleaning of the substrate surface by means of an arc, contaminants and oxide layers such as spontaneously forming natural oxide layers can be completely removed and an oxide layer can subsequently be generated on the cleaned substrate surface under controlled conditions. In this manner, a better adhesion of the thermal barrier coating structure on the substrate surface can be achieved than is possible with a thermal barrier coating manufactured in accordance with WO 03/087422 A1. It is furthermore possible to slow down the growth of metal oxides in operation using a thermal barrier coating manufactured in accordance with the invention and to achieve an improved temperature change resistance of the total thermal barrier coating system in which the thermal layer structure is used.

The above description of embodiments and variants only serves as an example. Further advantageous embodiments can be seen from the dependent claims and from the drawing. Furthermore, individual features from the embodiments and variants described or shown can also be combined with one another within the framework of the present invention to form new embodiments.

The invention will be explained in more detail in the following with reference to the embodiments and to the drawing. There are shown:

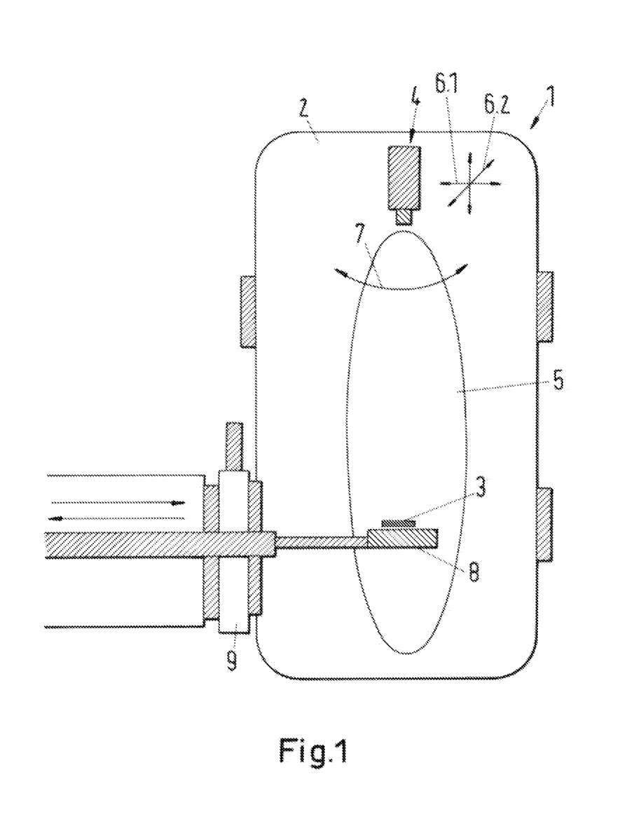

FIG. 1 an embodiment of a plasma coating plant for manufacturing a thermal barrier coating in accordance with the present invention;

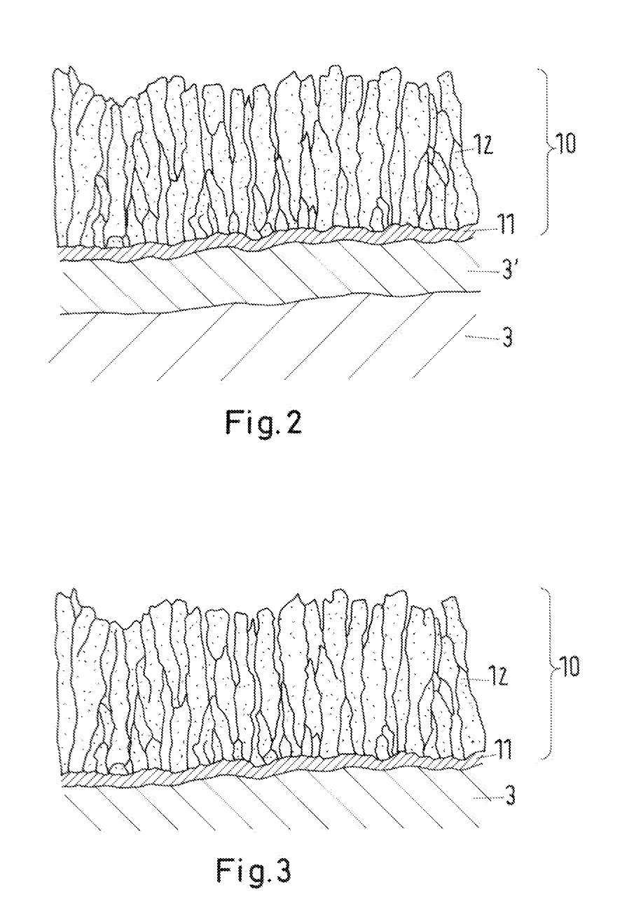

FIG. 2 an embodiment of a thermal barrier coating system with a thermal barrier coating structure manufactured in accordance with the present invention; and

FIG. 3 an embodiment of a thermal barrier coating structure manufactured in accordance with the present invention on any desired metallic substrate.

FIG. 1 shows an embodiment of a plasma coating plant for manufacturing a thermal barrier coating structure in accordance with the present invention. The plasma coating plant 1 includes a working chamber 2 having a plasma torch 4 for generating a plasma jet 5, a controlled pump apparatus which is not shown in FIG. 1 and which is connected to the working chamber 2 to set the pressure in the working chamber and a substrate holder 8 for holding the substrate 3. The plasma torch 4, which can be configured, for example, as a DC plasma torch, advantageously has a supplied electric power of at least 60 kW, 80 kW or 100 kW to generate a plasma with sufficiently high enthalpy so that thermal barrier coatings can be manufactured with a columnar structure. The pressure in the working chamber 2 is expediently settable between 2 Pa and 100 kPa or between 5 Pa and 20 kPa. As required, the plasma coating plant 1 can additionally include one or more injection apparatus to inject one or more components into the plasma or into the plasma jet in solid, liquid and/or gaseous form.

The plasma torch is typically connected to a power supply, for example to a direct current power supply for a DC plasma torch, and/or to a cooling apparatus and/or to a plasma gas supply and, on a case by case basis, to a supply for liquid and/or gaseous reactive components and/or to a conveying apparatus for spray powder or suspensions. The process gas or plasma gas can, for example, include argon, nitrogen, helium or hydrogen or a mixture of Ar or He with nitrogen and/or hydrogen or can be composed of one or more of these gases.

In an advantageous embodiment variant, the substrate holder 8 is configured as a displaceable bar holder to move the substrate out of an antechamber through a sealing sluice 9 into the working chamber 2. The bar holder additionally makes it possible to rotate the substrate, if necessary, during the treatment and/or coating.

In a further advantageous embodiment variant, the plasma coating plant 1 additionally includes a controlled adjustment apparatus for the plasma torch 4, which is not shown in FIG. 1, to control the direction of the plasma jet 5 and/or the spacing of the plasma torch from the substrate 3, for example in a range from 0.2 m to 2 m or 0.3 m to 1.2 m. On a case by case basis, one or more pivot axles can be provided in the adjustment apparatus to carry out pivot movements 7. The adjustment apparatus can furthermore also include additional linear adjustment axles 6.1, 6.2 to arrange the plasma torch 4 over different regions of the substrate 3. Linear movements and pivot movements of the plasma torch allow a control of the substrate treatment and substrate coating, for example to preheat a substrate uniformly over the total surface or to achieve a uniform layer thickness and/or layer quality on the substrate surface.

An embodiment of the method in accordance with the invention of manufacturing a thermal barrier coating structure on a substrate surface will be described in the following with reference to FIGS. 1, 2 and 3. In the method, a working chamber 2 having a plasma torch 4 is provided, a plasma jet 5 is generated in that a plasma gas is conducted through the plasma torch and is heated therein by means of electric gas discharge and/or electromagnetic induction and/or microwaves, and the plasma jet 5 is directed onto the surface of a substrate 3 introduced into the working chamber 2. In the method, a voltage is additionally applied between the plasma torch 4 and the substrate 3 to generate an arc between the plasma torch and the substrate, and the substrate surface is cleaned by means of the arc, wherein the substrate remains in the working chamber after the arc cleaning. An oxide layer 11 having a thickness of 0.02 μm to 5 μm or 0.02 μm to 2 μm is generated on the substrate surface cleaned in this manner and in a further step at least one thermal barrier coating 12 is applied by means of a plasma spray process. The substrate 3 advantageously remains in the working chamber 2 during the manufacture of the thermal barrier coating structure.

In a typical embodiment variant, the substrate 3 and/or the substrate surface is metallic, wherein the substrate can, for example, be a turbine blade of a Ni alloy or of a Co alloy and the substrate surface is typically formed by an adhesion promoting layer and/or a hot gas corrosion protective layer 3′, for example a layer of a metallic aluminide such as NiAl, NiPitAl or PtAl or an alloy of the type MCrAlY, where M=Fe, Co, Ni or a combination of Ni and Co. As required, in addition a barrier layer can be provided between the substrate 3 and the adhesion promoting layer and/or a hot gas corrosion protective layer 3′ (not shown in FIGS. 2 and 3), wherein the barrier layer is advantageously configured as metallic and can, for example, contain NiAl or NiCr.

The application of the barrier layer and/or adhesion promoting layer and/or hot gas corrosion protective layer can, if desired, take place within the framework of the method of manufacturing a thermal barrier coating structure. In an advantageous embodiment, the barrier layer and/or adhesion promoting layer and/or hot gas corrosion protective layer is/are applied to the substrate surface, for example by means of a plasma spray process or by means of another suitable process, and the thermal barrier coating build-up is continued in that, as described above, the substrate surface thus generated is cleaned by means of an arc and, without removing the substrate 3 from the working chamber 2 after the arc cleaning, an oxide layer 11 having a thickness of typically 0.02 μm to 5 μm or 0.02 μm to 2 μm is generated on the substrate surface cleaned in this manner and in a further step at least one thermal barrier coating 12 is applied by means of a plasma spray process.

In a further advantageous embodiment, the composition and/or the pressure of the atmosphere in the working chamber 2 is/are monitored and/or controlled during the manufacture of the thermal barrier coating structure 10. In an advantageous embodiment variant, the pressure in the working chamber during the arc cleaning of the substrate surface amounts to less than 1 kPa or less than 200 Pa.

In a further advantageous embodiment variant, the working chamber 2 contains oxygen or a gas containing oxygen during the production of the oxide layer 11. The oxide layer 11 can, for example, be thermally generated in that the substrate surface is heated, for example, by the plasma jet 5 and/or by means of C radiators and/or inductively.

The oxide layer 11 can also be generated by means of PS-PVD or by means of a chemical process, for example by means of PS-CVD, wherein the pressure in the working chamber typically lies under 1 kPa, e.g. between 20 Pa and 200 Pa, and, where required, at least one reactive component is injected into the plasma and/or into the plasma jet in solid and/or liquid and/or gaseous form.

The oxide layer generated advantageously has a porosity of less than 3% or less than 1% and/or more than 90% or more than 95% is composed of a thermally stable oxide, in particular of more than 90% or more than 95% α-Al₂O₃.

In a further advantageous embodiment, the at least one thermal barrier coating 12 is manufactured from ceramic material, for example from an oxide ceramic material or from a material which contains oxide ceramic components, wherein the oxide ceramic material is, for example, a zirconium oxide stabilized with rare earths. The substance used as a stabilizer is added to the zirconium oxide in the form of an oxide of rare earths, for example yttrium, cerium, scandium, dysprosium or gadolinium, wherein in the case of yttrium oxide the portion typically amounts to 5 to 20% by weight.

In an advantageous embodiment variant, the at least one thermal barrier coating 12 is applied by means of thermal plasma spraying at a pressure in the working chamber of more than 50 kPa and/or by means of low pressure plasma spraying (LPPS) at a pressure in the work chamber of 5 kPa to 50 kPa.

In a further advantageous embodiment variant, the at least one thermal barrier coating 12 is applied by means of plasma spray physical vapor deposition (PS-PVD) at a pressure in the working chamber of less than 5 kPa and typically less than 1 kPa, wherein the ceramic material can, for example, be injected into a plasma defocusing the powder jet. The ceramic material is advantageously at least partly vaporized in the plasma jet so that, for example, at least 15% by weight or at least 20% by weight changes into the vapor phase to generate a thermal barrier coating having a columnar structure. The thermal barrier coating 12 can in this respect be built up by depositing a plurality of layers. The total layer thickness of the thermal barrier coating 12 typically has values between 50μ, and 2000 μm and preferably values of at least 100 μm.

A plasma torch 4 is required to apply the thermal barrier coating 12 and can, for example, be configured as a DC plasma torch and advantageously has a supplied electric power of at least 60 kW, 80 kW or 100 kW to generate a plasma with sufficiently high specific enthalpy so that thermal barrier coatings having a columnar structure can be manufactured by means of PS-PVD.

So that the powder jet is reshaped by the defocusing plasma during the PS-PVD process into a cloud of vapor and particles from which a layer with the desired columnar structure results, the powdery starting material must have a very fine grain. The size distribution of the starting material advantageously lies to a substantial part in the range between 1 μm and 50 μm, preferably between 3 μm and 25 μm.

In a further advantageous embodiment, the direction of the plasma jet and/or the spacing of the plasma torch from the substrate is/are controlled. The plasma jet can, for example, thus be conducted over the substrate surface on the cleaning of the substrate surface and/or on the heating of the substrate surface and/or generation of the oxide layer and/or on the application of the at least one thermal barrier layer to achieve a uniform treatment or coating.

Irrespective of the plasma spray process used, it may be advantageous to use an additional heat source to carry out the application and/or generation of the layers described in the above embodiments and variants within a preset temperature range. The temperature is typically preset in the range between 800° C. and 1300° C., advantageously in the temperature range >1000° C. An infrared radiator, e.g. a carbon radiator, and/or a plasma jet and/or a plasma and/or an induction heater can, for example, be used as the additional heat source. In this respect, the heat supply of the heat source and/or the temperature of the substrate to be coated can be controlled or regulated as required.

Before the application and/or generation of the layers described in the above embodiments and variants, the substrate 3 and/or the substrate surface is/are normally preheated to improve the adhesion of the layers. The preheating of the substrate can take place by means of plasma jet, wherein the plasma jet 5, which contains neither coating powder nor reactive components for the preheating, is conducted over the substrate with pivot movements.

FIGS. 2 and 3 respectively show an embodiment of a thermal barrier coating system having a thermal barrier coating structure manufactured in accordance with the present invention. The substrate 3 and/or the substrate surface is/are typically metallic, wherein the substrate surface, as shown in FIG. 2, can be formed for example, by an adhesion promoting layer and/or by a hot gas corrosion protective layer 3′, for example a layer of a metal aluminide such as NiAl, NiPtAl or PtAl or an alloy of the type MCrAlY, where M=Fe, Co, Ni or a combination of Ni and Co. If required, a barrier layer can moreover be provided between the substrate 3 and the adhesion promoting layer and/or the hot gas corrosion protective layer 3′ (not shown in FIGS. 2 and 3), wherein the barrier layer is advantageously configured as metallic and can, for example, be composed of NAl or NiCr. The barrier layer typically has a thickness between 1 μm to 20 μm and the adhesion promoting layer and/or the hot gas corrosion protection layer 3′ typically has a thickness between 50 μm and 500 μm.

The application of the barrier layer and/or adhesion promoting layer and/or hot gas corrosion protective layer can, if desired, take place within the framework of the method of manufacturing a thermal barrier coating structure. In an advantageous embodiment, the barrier layer and/or adhesion promoting layer and/or hot gas corrosion protective layer is/are applied to the substrate surface, for example by means of a plasma spray process or by means of another suitable process, and the thermal barrier coating build-up is continued in that, as described above, the substrate surface thus generated is cleaned by means of an arc and, without removing the substrate 3 from the working chamber 2 after the arc cleaning, an oxide layer 11 having a thickness of typically 0.02 μm to 5 μm or 0.02 μm to 2 μm is generated on the substrate surface cleaned in this manner and in a further step at least one thermal barrier coating 12 is applied by means of a plasma spray process.

If required, a smoothing layer, now shown in FIGS. 2 and 3, can additionally be applied to the thermal barrier coating 12 and can, for example be composed of oxide ceramic material such as ZrO₂ or SiO₂ and have a thickness of typically 0.2 μm to 50 μm, preferably 1 μm to 20 μm. The smoothing layer is advantageously applied by means of PS-PVD in that, for example, one or more components are injected into the plasma or into the plasma jet in solid, liquid and/or gaseous form.

The individual steps of the method of manufacturing a thermal barrier coating structure on a substrate surface are preferably carried out in a single work cycle without removing the substrate 3 from the working chamber 2 during the process.

The invention further includes a substrate manufactured using the above-described method or using one of the above-described embodiments and variants.

The method described above of manufacturing a thermal barrier coating structure on a substrate surface as well as the associated embodiments and variants have the advantage that a high-quality oxide layer, for example an α-Al₂O₃ layer, can be generated on the cleaned substrate surface thanks to which an improved temperature change resistance of the total thermal barrier coating system can be achieved.

1. A method of manufacturing a thermal barrier coating structure on a substrate surface, wherein
a working chamber having a plasma torch is provided;
a plasma jet is generated in that a plasma gas is conducted through the plasma torch and is heated therein by means of electric gas discharge and/or electromagnetic induction and/or microwaves; and
the plasma jet is directed to the surface of a substrate introduced into the working chamber,
wherein
a voltage is applied between the plasma torch and the substrate to generate an arc between the plasma torch and the substrate and the substrate surface is cleaned by means of the arc;
the substrate remains in the working chamber after the arc cleaning and an oxide layer is generated on the substrate surface cleaned in this manner having a thickness of 0.02 μm to 5 μm, in particular from 0.02 μm to 2 μm; and
in a further step at least one thermal barrier coating is applied by means of a plasma spray process.

2. A method in accordance with claim 1, wherein the substrate surface is formed by at least one of an adhesion promoting layer and a hot gas corrosion protective layer.

3. A method in accordance with claim 1, wherein the substrate remains in the working chamber during the manufacture of the thermal barrier coating structure.

4. A method in accordance with claim 1, wherein at least one of the composition and the pressure of the atmosphere in the working chamber is at least one of monitored and controlled during the manufacture of the thermal barrier coating structure.

5. A method in accordance with claim 1, wherein the pressure in the working chamber amounts to less than 1 kPa during the arc cleaning of the substrate surface.

6. A method in accordance with claim 1, wherein the working chamber contains oxygen or a gas containing oxygen during the generation of the oxide layer.

7. A method in accordance with claim 1, wherein the oxide layer is thermally generated, in particular in that the substrate surface is heated by the plasma jet.

8. A method in accordance with claim 1, wherein the oxide layer is generated by means of PS-PVD or PS-CVD, while the pressure in the working pressure is below 1 kPa; and wherein in particular at least one reactive component is injected into the plasma jet in liquid or gaseous form.

9. A method in accordance with claim 1, wherein the oxide layer generated has a porosity of less than 3%, in particular of less than 1%; and/or wherein more than 90% or more than 95% of the oxide layer generated is formed from a thermally stable oxide, in particular more than 90% or than 95% from α-Al₂O₃.

10. A method in accordance with claim 1, wherein the at least one thermal barrier coating is manufactured from ceramic material.

11. A method in accordance with claim 10, wherein the ceramic material of the thermal barrier coating is composed of stabilized zirconium oxide, in particular of zirconium oxide stabilized with yttrium, cerium, scandium, dysprosium or gadolinium, and/or contains stabilized zirconium oxide or zirconium oxide stabilized with yttrium, cerium, scandium, dysprosium or gadolinium as a component.

12. A method in accordance with claim 10, wherein at least one thermal barrier coating is applied by means of thermal plasma spray at a pressure in the working chamber of more than 50 kPa and/or by means of low pressure plasma spray at a pressure in the working chamber of 5 kPa to 50 kPa.

13. A method in accordance with claim 10, wherein at least one thermal barrier coating is applied by means of plasma spray physical vapor deposition at a pressure in the working chamber of less than 5 kPa or less than 1 kPa.

14. A method in accordance with claim 13, wherein the ceramic material is at least partly vaporized in the plasma jet to generate a thermal barrier coating having a columnar structure.

15. A substrate manufactured using a method in accordance with claim 1.

16. A method in accordance with claim 2, wherein the at least one of the adhesion promoting layer and the hot gas corrosion protective layer is an alloy of the type MCrAlY, wherein M=Fe, Co, Ni or NiCo, or of a metallic aluminide.
